(19) United States
(12) Patent Application Publication
(10) Pub. No.: US 2003/0002600 A1
(43) Pub. Date: Jan. 2, 2003

(54) FSK/GFSK demodulator with digital frequency offset compensation and the demodulating method of the same

(76) Inventors: Dsun-Chie Twu, Hsinchu (TW); Shih-Yu Ku, Hsinchu (TW)

Correspondence Address: Raymond Sun, 12420 Woodhall Way, Tustin, CA, 92782, US

(21) Appl. No.: 10/174,877

(22) Filed: Jun. 18, 2002

(30) Foreign Application Priority Data
Jun. 21, 2001 (TW) 90115355

(51) Int. Cl. H03D 3/00

(52) U.S. Cl. 375/334; 329/300

(57) ABSTRACT

The present invention discloses an FSK/GFSK demodulator with digital frequency offset compensation, comprising: an FSK/GFSK signal demodulator, for receiving a transmission signal from an antenna and generating an inter-medium frequency (base-frequency) signal after amplification and filtering; an analog-to-digital converter (ADC), for receiving the inter-medium frequency (base-frequency) signal from the FSK/GFSK signal demodulator and converting the signal into a digital signal; a digital frequency discriminator, for receiving the digital signal from the analog-to-digital converter and generating a discriminated signal; a digital band-pass filter, for filtering off a high-frequency component and a DC component of the discriminated signal and generating a demodulated signal; and a data slicer, for receiving the demodulated signal and generating a received signal. The digital band-pass filter is composed of a digital low-pass filter and a digital high-pass filter connected in series. The FSK/GFSK demodulator with digital compensation for frequency offset according to the present invention employs a digital filter unit to filter off the direct-current (DC) component of the frequency offset of the discriminated signal, and generates a demodulated signal independent of the DC component of the frequency offset. Therefore, the data slicer can correctly determine the demodulated signal without the DC level.

### BACKGROUND OF THE INVENTION

1. Field of the Invention

The present invention generally relates to a compensation device for frequency offset and, more particularly, to a frequency shift keying (FSK)/Gaussian frequency shift (GFSK) demodulator with digital frequency offset compensation and the demodulating method of the same. The FSK/GFSK demodulator of the present invention employs a digital filter to filter off the direct-current (DC) component of the frequency offset of the FSK/GFSK demodulator.

2. Description of the Prior Art

Due to the limitations such as size and cost, frequency synthesizers, quartz oscillators and other devices providing high precision oscillating frequencies fail to generate radio frequencies. Therefore, a general radio-frequency unit performs frequency offset between a transmission side and a reception side by using automatic frequency control.

FIG. 1 is a schematic block diagram showing a conventional FSK/GFSK demodulator. As shown in the figure, the receiver 10 comprises an antenna 11, a RF-to-IF down converter 12, a frequency discriminator 13, and a data output unit 14. The RF-to-IF down converter 12 filters and amplifies a signal received by the antenna 11, and further comprises a band-pass filter 121 for extracting a signal having a necessary band from the received signal, a RF amplifier 122 for amplifying the level of the signal passing through the band-pass filter to a necessary level, a mixer 123 for decreasing the frequency of the received signal to a necessary frequency, an oscillator 124 for generating the necessary frequency, a IF amplifier 125 for amplifying the level of the received signal to a necessary level, and a limiter 126 for limiting the amplitude of the received signal. The antenna 11 receives a radio-frequency signal emitted from a transmission side (not shown), and then generates a signal to be transmitted to the RF-to-IF down converter 12. The RF-to-IF down converter 12 extracts the required frequency range from the received signal, and outputs a signal representing the frequency range after amplification. Finally, the frequency discriminator 13 demodulates the output signal and the demodulated signal is output from the output unit 14. However, in such a communication system, the frequency offset of the carrier between the transmission side and the reception side may lead to a DC component included in the output signal from the frequency discriminator 13, which may cause malfunction of the output unit 14.

The output unit of a conventional FSK/GFSK receiver employs an analog low-pass filter composed of a resistor 142 and a capacitor 144 so as 10 to obtain a DC level of the output signal from the frequency discriminator 13. The DC level is then compared to the output signal from the frequency discriminator 13 by a comparator 145 so as to obtain a demodulated signal. The output signal from the frequency discriminator 13 charges the capacitor 144 via a buffer 141 and the resistor 142 and a control switch 143 controls the time so as to obtain the DC level from the frequency discriminator 13. Finally, the control switch 143 is turned off so as to generate a correct demodulated signal based on a voltage stored in the capacitor 144 as a level for the comparator 145.

However, the output unit 14 has several problems that may adversely affect the correctness of the demodulated signal. Firstly, the switching time of the control switch 143 strongly depends on the correctness of the obtained DC level. Secondly, the resistance/capacitance values of the resistor 142 and the capacitor 144 must be evaluated respectively according to the associate system. Thirdly, the control switch 143 is controlled by a next-stage control unit (not shown) that may increase the cost.

### SUMMARY OF THE INVENTION

Accordingly, it is the primary object of the present invention to provide an FSK/GFSK demodulator with digital frequency offset compensation and the demodulating method of the same. The FSK/GFSK demodulator employs a digital filter unit to filter off the direct-current (DC) component of the frequency offset.

In order to achieve the foregoing object, the present invention provides an FSK/GFSK demodulator with digital frequency offset compensation, comprising: an FSK/GFSK signal demodulator, for receiving a transmission signal from an antenna and generating an inter-medium frequency (base-frequency) signal after amplification and filtering; an analog-to-digital converter (ADC), for receiving the an inter-medium frequency (base-frequency) signal from the FSK/GFSK signal demodulator and converting the signal into a digital signal; a digital frequency discriminator, for receiving the digital signal from the analog-to-digital converter and generating a discriminated signal; a digital band-pass filter, for filtering off a high-frequency component and a DC component of the discriminated signal and generating a demodulated signal; and a data slicer, for receiving the demodulated signal and generating a received signal. The digital band-pass filter is composed of a digital low-pass filter and a digital high-pass filter connected in series. The FSK/GFSK demodulator with digital compensation for frequency offset according to the present invention employs a digital filter unit to filter off the direct-current (DC) component of the frequency offset of the discriminated signal, and generates a demodulated signal independent of the DC component of the frequency offset. Therefore, the data slicer can correctly determine the demodulated signal without the DC level.

Other and further features, advantages and benefits of the invention will become apparent in the following description taken in conjunction with the following drawings. It is to be understood that the foregoing general description and following detailed description are exemplary and explanatory but are not to be restrictive of the invention. The accompanying drawings are incorporated in and constitute a part of this application and, together with the description, serve to explain the principles of the invention in general terms. Like numerals refer to like parts throughout the disclosure.

### BRIEF DESCRIPTION OF THE DRAWINGS

The objects, spirits and advantages of the preferred embodiments of the present invention will be readily understood by the accompanying drawings and detailed descriptions, wherein:

FIG. 1 is a schematic block diagram showing a conventional FSK/GFSK demodulator in accordance with the prior art;

FIG. 2 is a schematic block diagrams showing an FSK/GFSK demodulator with digital frequency offset compensation in accordance with the present invention;

FIG. 3 is a schematic block diagrams showing one embodiment of some devices in FIG. 2;

FIG. 4 is a graph showing a waveform of a signal B output from the low-pass filter without being digitally filtered in accordance with FIG. 3;

FIG. 5 is a graph showing a waveform of a signal A output from the low-pass filter, which is digitally filtered, in accordance with FIG. 3; and

FIG. 6 is a flow chart showing a receiving method of an FSK/GFSK signal with digital frequency offset compensation in accordance with the present invention.

### DETAILED DESCRIPTION OF THE INVENTION

The present invention providing an FSK/GFSK demodulator with digital frequency offset compensation and the demodulating method of the same can be exemplified by the preferred embodiments as described hereinafter.

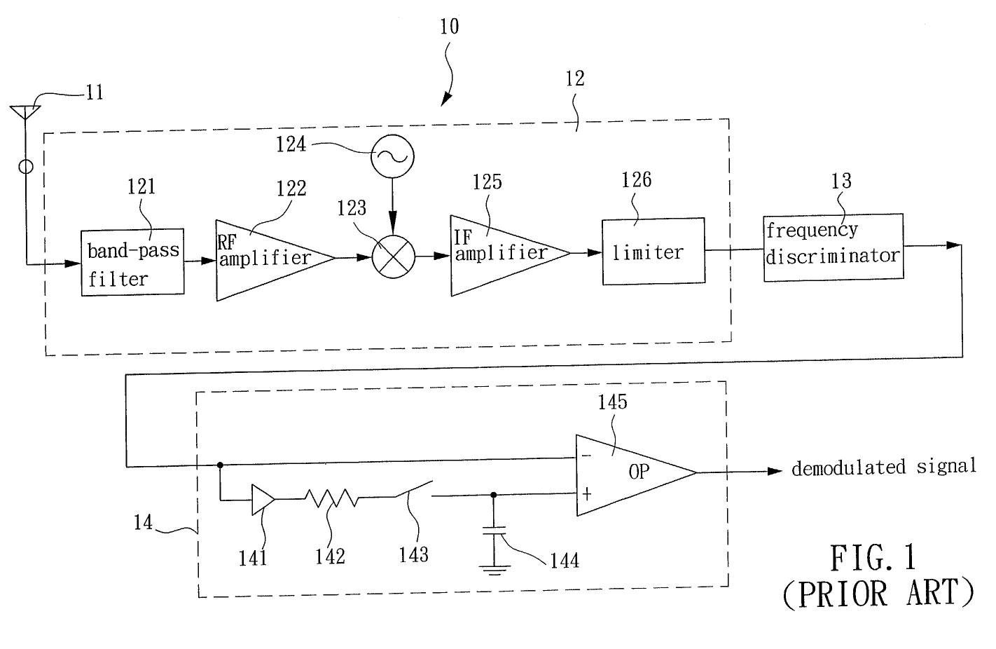

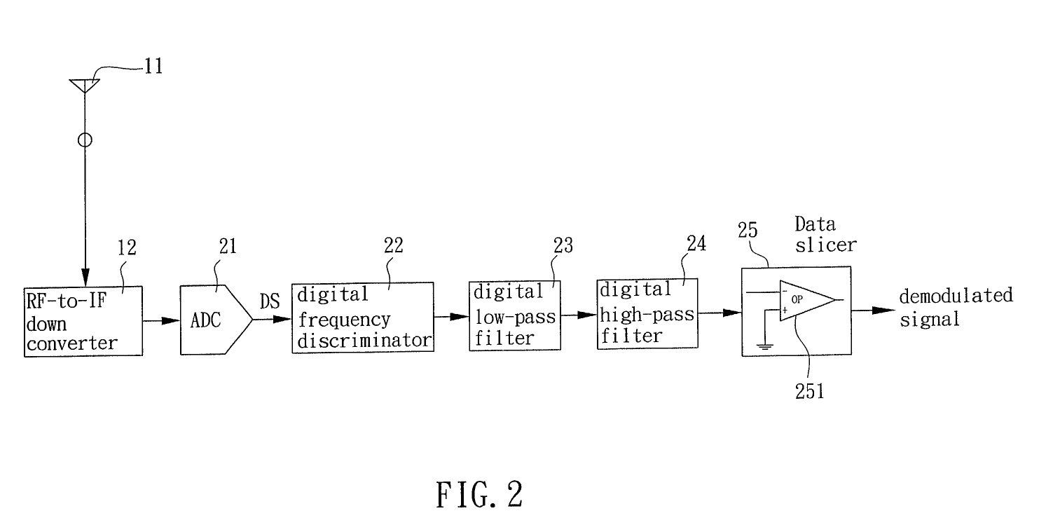

Please refer to FIG. 2, which is a schematic block diagrams showing an FSK/GFSK demodulator with digital frequency offset compensation in accordance with the present invention. In the figure, the FSK/GFSK demodulator according to the present invention is similar to the conventional FSK/GFSK demodulator (shown in FIG. 1), both comprising an antenna 11 and a RF-to-IF down converter 12. Most of the elements used in the FSK/GFSK demodulator according to the present invention are the same as those used in the conventional FSK/GFSK demodulator (shown in FIG. 1). Therefore, repeated description is omitted.

Moreover, the FSK/GFSK demodulator according to the present invention further comprises an analog-to-digital converter (ADC) 21, a digital frequency discriminator 22, a finite impulse response digital low-pass filter 23, an infinite impulse response digital filter 24, and a data slicer 25. The analog-to-digital converter 21 receives a signal from the RF-to-IF down converter 12 and converts the signal into a digital signal (DS). The digital signal is then discriminated by the digital frequency discriminator 22 to be a discriminated signal with a certain frequency. The discriminated signal is later filtered by the finite impulse response digital low-pass filter 23 to filter off the high-frequency component of the discriminated signal and generating a first demodulated signal. Furthermore, first demodulated signal is filtered by the infinite impulse response digital filter 24 to filter off the DC component so as to obtain a second demodulated signal without the DC component. The second demodulated signal is converted by the data slicer 25 to obtain a received signal. Since the second demodulated signal generated by the infinite impulse response digital filter 24 does not have the DC component, the data slicer 25 only needs a comparator 251, and the demodulated signal will not be affected by the DC offset voltage.

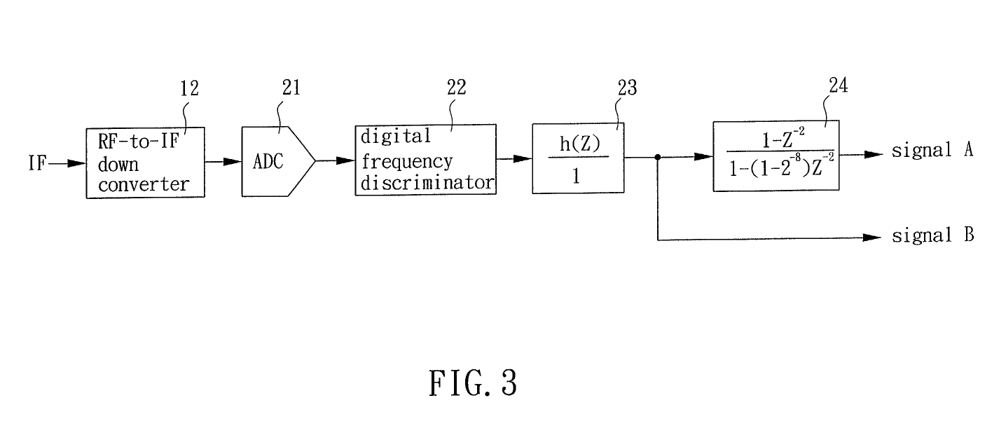

FIG. 3 is a schematic block diagrams showing one embodiment of some devices in FIG. 2. In this embodiment, the frequency of the input inter-mid frequency signal is 1 MHz. The symbol rate of the signal is 1 Mbps, and the sampling rate of the analog-to-digital converter 21 fs=32 MHz. Moreover, the transfer function of the finite impulse response digital low-pass filter 23 is h(z)=h₀+h₁z⁻¹+ . . . +h₆₃z⁻⁶³, the pass-band is in the range from 0 to 0.2 MHz, and the stop-band is above 2 MHz. The design of the parameters in h(z) is well-known in the conventional digital signal processing, as described in related literatures and computer-aided design soft-wares (for example, Signal Processing Toolbox of MATLAB^{R}). Furthermore, the transfer function of the infinite impulse response digital filter 24 is

$$g ( z ) = \frac{1 - {z}^{- 2}}{1 - ( 1 - {2}^{- 8} ) {z}^{- 2}} .$$

Since the frequency response of the digital filter is

$$G ( f ) = g ⌊ {ⅇ}^{j \frac{2 π f}{fs}} ⌋ ,$$

it is found that the frequency response of the digital filter is 0 when the frequency f=0 Hz and f=16 MHz. Since the frequency component over 2 MHz of the first demodulated signal has been filtered off by the finite impulse response digital low-pass filter 23, the infinite impulse response digital filter 24 is used for filtering off the DC component of the demodulated signal. Moreover, the finite impulse response digital low-pass filter 23 and the infinite impulse response digital filter 24 can be exchanged in their positions. Alternatively, a band-pass filter according to the prior art digital signal processing can be used to replace the digital low-pass filter and the digital high-pass filter connected in series, so as to filter off both the high-frequency component and the DC component of the discriminated signal.

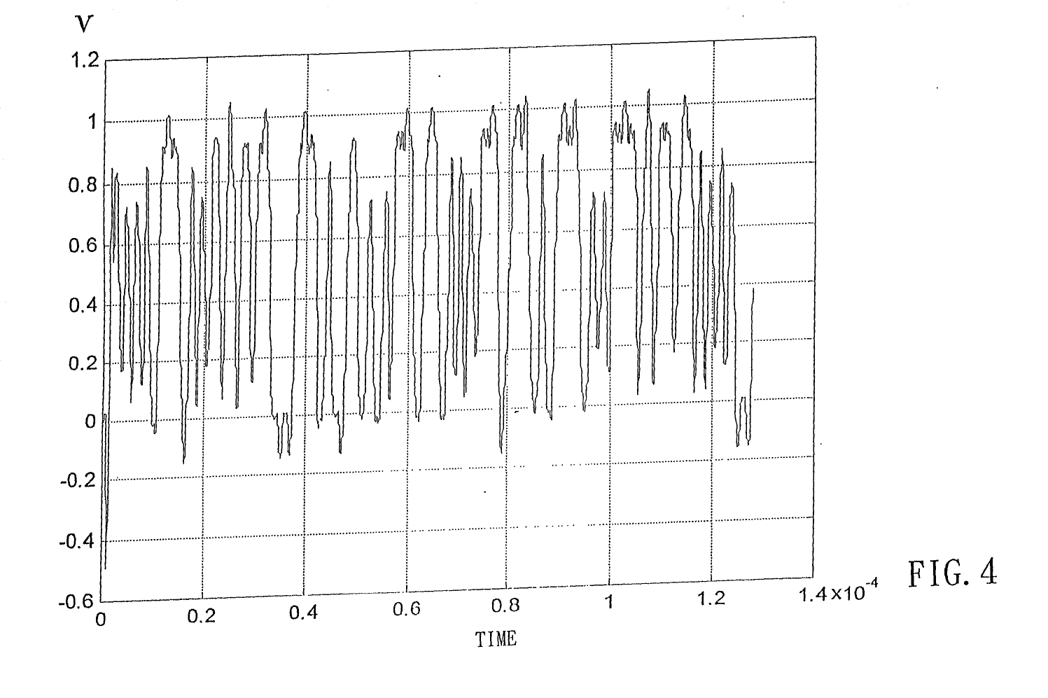

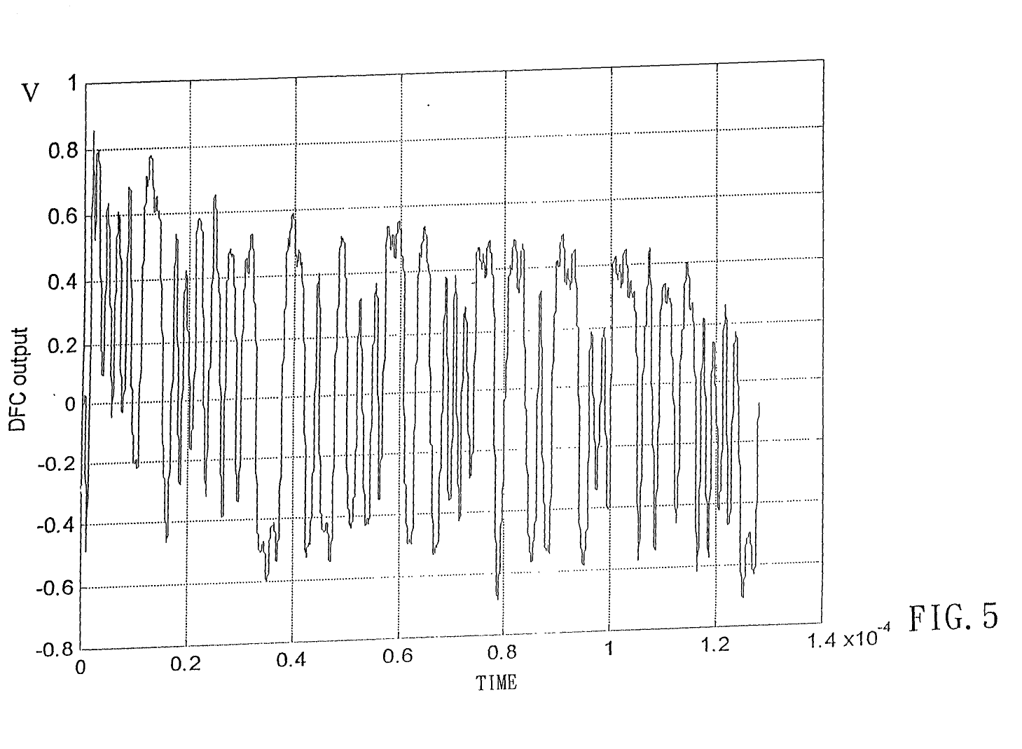

FIG. 4 is a graph showing a waveform of a signal B output from the finite impulse response digital low-pass filter 23 without being digitally filtered by the infinite impulse response digital filter 24 in accordance with FIG. 3. As shown in the figure, the output signal from the finite impulse response digital low-pass filter 23 exhibits a DC offset voltage of about 0.4 A due to the frequency offset of about −150 kHz. However, as shown in FIG. 5, which is a graph showing a waveform of a signal A output from the finite impulse response digital low-pass filter 23 to be digitally filtered by the infinite impulse response digital filter 24 in accordance with FIG. 3, the output signal from the finite impulse response digital low-pass filter 23 exhibits no more DC offset voltage after filtered by the infinite impulse response digital filter 24.

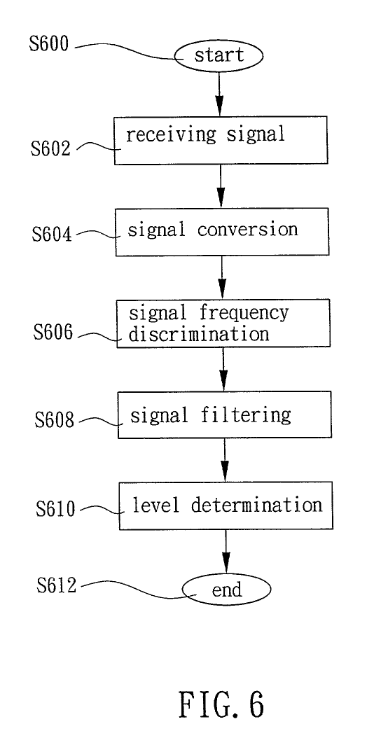

FIG. 6 is a flow chart showing a demodulating method of an FSK/GFSK signal with digital frequency offset compensation in accordance with the present invention. According to the present invention, the method comprises steps of:

Step S600: start;

Step S602: receiving a signal, wherein a transmission signal from an antenna is received and an inter-medium frequency (base frequency) signal is generated after amplification and filtering;

Step S604: signal conversion, wherein the inter-medium frequency (base frequency) signal is converted into a digital signal;

Step S606: signal frequency discrimination, wherein the frequency of the digital signal is discriminated and a discriminated signal is generated;

Step S608: signal filtering, wherein a high-frequency component and a low-frequency component of the discriminated signal are filtered off and a demodulated signal is generated;

Step S610: level determination, wherein the level of the demodulated signal is determined and a received signal is generated; and

Step S612: End.

To be more particularly, in Step S608 according to the present invention, a band-pass filter is used to filter off the high-frequency component and the low-frequency component, and generate a demodulated signal independent of the DC component of the frequency offset. Therefore, the data slicer can correctly determine the demodulated signal without the DC level. Moreover, the band-pass filter is composed of a finite impulse response digital low-pass filter and an infinite impulse response digital filter 24 connected in series.

According to the above discussion, the present invention discloses an FSK/GFSK demodulator with digital frequency offset compensation and a demodulating method of the same. Therefore, the present invention has been examined to be progressive, advantageous and applicable to the industry.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. An FSK/GFSK demodulator with digital frequency offset compensation, comprises:
a RF-to-IF down converter, for receiving a transmission signal from an antenna and generating an inter-medium frequency (base-frequency) signal after filtering and amplifying;
an analog-to-digital converter (ADC), for receiving said inter-medium frequency (base-frequency) signal from said FSK/GFSK signal demodulator and converting said signal into a digital signal;
a digital frequency discriminator, for receiving said digital signal from said analog-to-digital converter and generating a discriminated signal;
a digital band-pass filter, for filtering off a high-frequency component and a DC component of said discriminated signal and generating a demodulated signal; and
a data slicer, for receiving said demodulated signal and generating a received signal.

2. The FSK/GFSK demodulator with digital frequency offset compensation as recited in claim 1, wherein said digital band-pass filter is composed of a digital low-pass filter and a digital high-pass filter.

3. The FSK/GFSK demodulator with digital frequency offset compensation as recited in claim 2, wherein said digital low-pass filter is a finite impulse response digital low-pass filter.

4. The FSK/GFSK demodulator with digital frequency offset compensation as recited in claim 2, wherein said digital high-pass filter is a infinite impulse response digital high-pass filter.

5. An FSK/GFSK demodulator with digital frequency offset compensation, comprises:
a RF-to-IF down converter, for receiving a transmission signal from an antenna and generating an inter-medium frequency (base-frequency) signal after amplification and filtering;
an analog-to-digital converter (ADC), for receiving said inter-medium frequency (base-frequency) signal from said FSK/GFSK signal demodulator and converting said signal into a digital signal;
a digital frequency discriminator, for receiving said digital signal from said analog-to-digital converter and generating a discriminated signal;
a digital low-pass filter, for filtering off a high-frequency component of said discriminated signal and generating a first demodulated signal;
a digital high-pass filter, for filtering off a DC component of said first demodulated signal and generating a second demodulated signal; and
a data slicer, for receiving said second demodulated signal and generating a received signal.

6. The FSK/GFSK demodulator with digital frequency offset compensation as recited in claim 5, wherein said digital low-pass filter is a finite impulse response digital low-pass filter.

7. The FSK/GFSK demodulator with digital frequency offset compensation as recited in claim 2, wherein said digital high-pass filter is a infinite impulse response digital high-pass filter.

8. An FSK/GFSK demodulator with digital frequency offset compensation, comprises:
a RF-to-IF down converter, for receiving a transmission signal from an antenna and generating an inter-medium frequency (base-frequency) signal after amplification and filtering;
an analog-to-digital converter (ADC), for receiving said inter-medium frequency (base-frequency) signal from said FSK/GFSK signal demodulator and converting said signal into a digital signal;
a digital low-pass filter, for filtering off a high-frequency component of said discriminated signal and generating a first demodulated signal;
a digital frequency discriminator, for receiving said digital signal from said analog-to-digital converter and generating a discriminated signal;
a digital high-pass filter, for filtering off a DC component of said first demodulated signal and generating a second demodulated signal; and
a data slicer, for receiving said second demodulated signal and generating a received signal.

9. The FSK/GFSK demodulator with digital frequency offset compensation as recited in claim 8, wherein said digital high-pass filter is a infinite impulse response digital high-pass filter.

10. The FSK/GFSK demodulator with digital frequency offset compensation as recited in claim 8, wherein said digital low-pass filter is a finite impulse response digital low-pass filter.

11. A demodulating method of an FSK/GFSK signal with digital frequency offset compensation, comprising steps of:
receiving a signal, wherein a transmission signal from an antenna is received and an inter-medium frequency (base frequency) signal is generated after filtering and amplifying;
signal conversion, wherein said inter-medium frequency (base frequency) signal is converted into a digital signal;
signal frequency discrimination, wherein the frequency of said digital signal is discriminated and a discriminated signal is generated;
signal filtering, wherein a high-frequency component and a low-frequency component of said discriminated signal are filtered off and a demodulated signal is generated; and
level determination, wherein the level of said demodulated signal is determined and a received signal is generated.

12. The method of claim 11, wherein receiving a signal further comprising:
extracting the transmission signal received from the antenna to generate a extracted signal;
amplifying the extracted signal to generate a first amplified signal;
decreasing the frequency of the first amplified signal to a decreased-frequency signal;
amplifying the decreased-frequency signal to generate a second amplified signal; and
limiting the amplitude of the second amplified signal to generate the inter-medium frequency (base frequency) signal.
